(19) United States
(12) Patent Application Publication
(10) Pub. No.: US 2010/0307554 A1
(43) Pub. Date: Dec. 9, 2010

(54) Solar Roman Blinds

(76) Inventor: Robert J. Migliozzi, Olney, MD (US)

Correspondence Address: Robert J Migliozzi II, 4611 Winding Stone Circle, Olney, MD, 20832, US

(21) Appl. No.: 12/481,399

(22) Filed: Jun. 9, 2009

(51) Int. Cl. H01L 31/042; E06B 9/24

(52) U.S. Cl. 136/244; 160/84.02

(57) ABSTRACT

A vertical solar collector system having several slat-like members each of which has a custom design and radiation-reflecting surface and a heat exchange mechanism, radiation being reflected from the reflecting surface of one member of the collector to the heat exchange mechanism of another member. The members can be oriented to provide energy collection during certain periods of time and then re-oriented to provide a thermal insulating function.

### FIELD OF THE INVENTION

The present invention relates to solar collector systems and, more particularly, to solar collector systems wherein the collector serves as well to effect design and thermal insulation of a heated space

### BACKGROUND OF THE INVENTION

The major problem with windows of dwellings, office buildings, greenhouses, etc., which are exposed to the sun all or part of the day is that they admit too much of the incoming solar radiation and are a major source of heat loss during cold days when the sun is not shining at them. The problem is normally handled by coating or tinting the glass to reflect a large part of the incoming radiation. This available energy is thus lost. To reduce heat loss when the sun is not shining on them, double thicknesses of glass with insulating space between are used or windows are covered with heavy drapes or venetian blinds.

Accordingly, a principal object of the present invention is to provide a decorative solar collector that provides very effective collection of solar energy, but provides, as well, custom interior designs with thermal insulation during time periods when such energy is not available or not needed.

Another object is to provide a solar roman blinds and system that can be retrofitted into existing structures and, in particular, in the window areas of such structures.

Still another object is to provide decorative solar roman blinds for such window areas to intercept all the incoming solar radiation but one which, nevertheless, permits considerable visibility through the window.

### SUMMARY OF THE INVENTION

Solar Roman Blinds are comprised of two main elements Roman Blinds and Flexible Solar Panels. Roman blinds are a standard item in alot of households. The main function is providing privacy and to block out sun light to reduce the energy consumption in a home. I have decided to use that sunlight that is being blocked out by normal roman blinds to produce solar power. The solar panel is attached to the Roman Blinds to capture the sunlight and produce solar power without the need to place solar panels on the roof of traditional homes.

The invention of Solar Roman Blinds, provides a way to capture the sun's power on the Flexible Solar Panel Side 20 and allow for the interior view to have the true look of Roman Blinds 10. All without the need to place traditional solar panels on the roof of homes. This design allows for the traditions use of roman blinds to be in a up or down position, but more importantly capturing the maximum energy of the sun while they are down. Also, by having the flexible solar panels intergrated within roman blinds, the panels themselves will not be exposed to weather elements and damage.

### BRIEF DESCRIPTION OF THE DRAWING

Drawing Views

FIG. 1—Exterior View—Blinds Down

FIG. 2—Interior View—Blinds Down

FIG. 3—Exterior View—Blinds Up

FIG. 4—Interior View—Blinds Up

FIG. 5—Detail Assembly

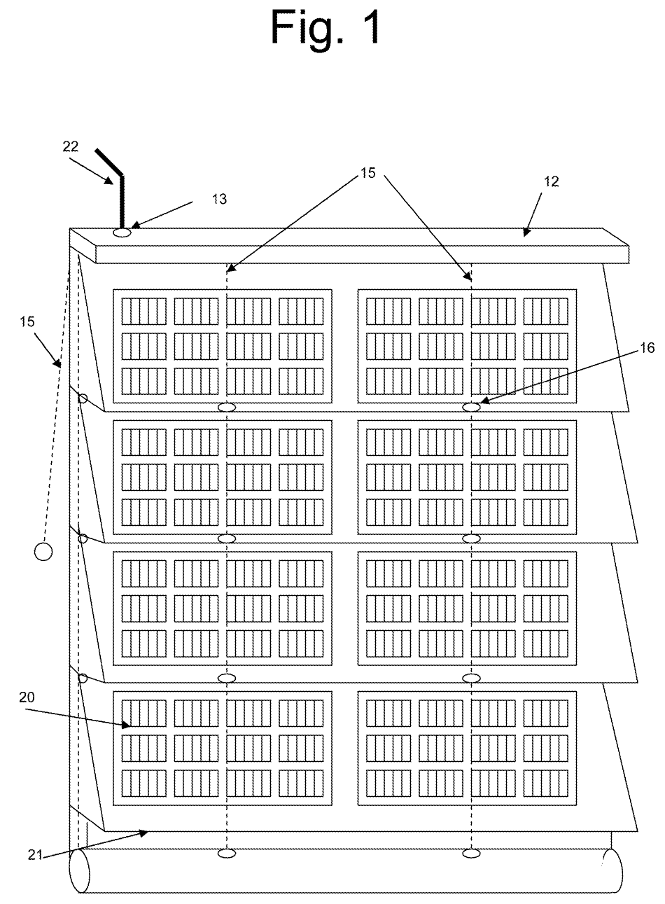

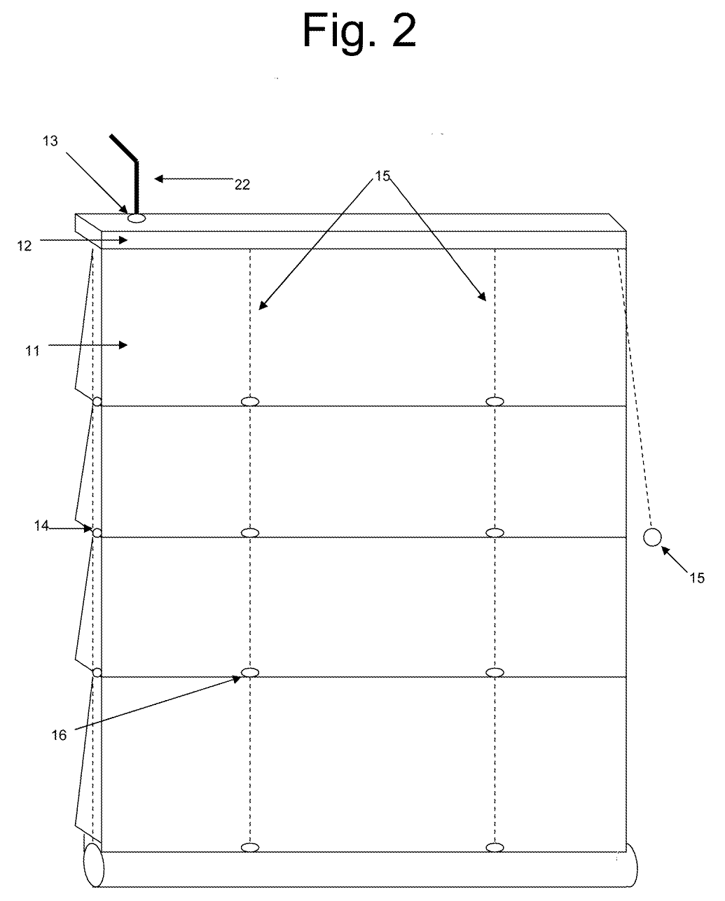

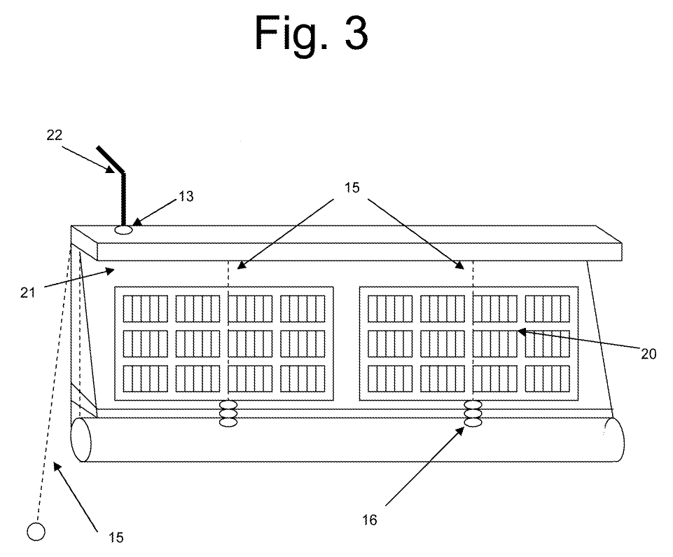

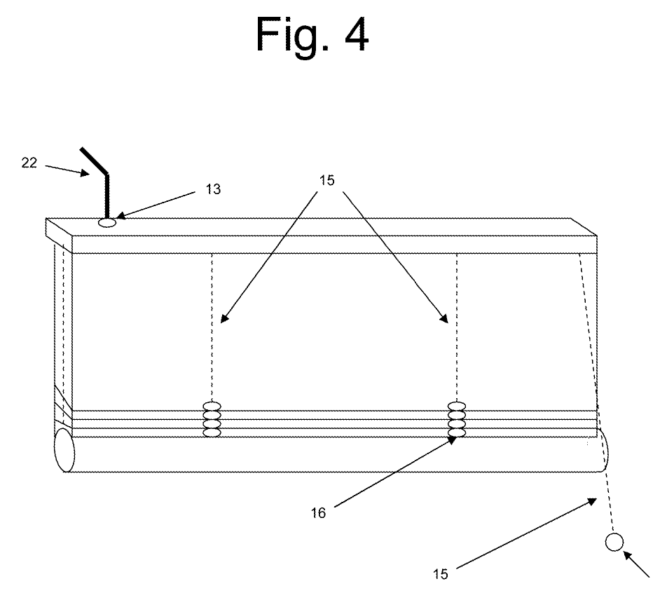

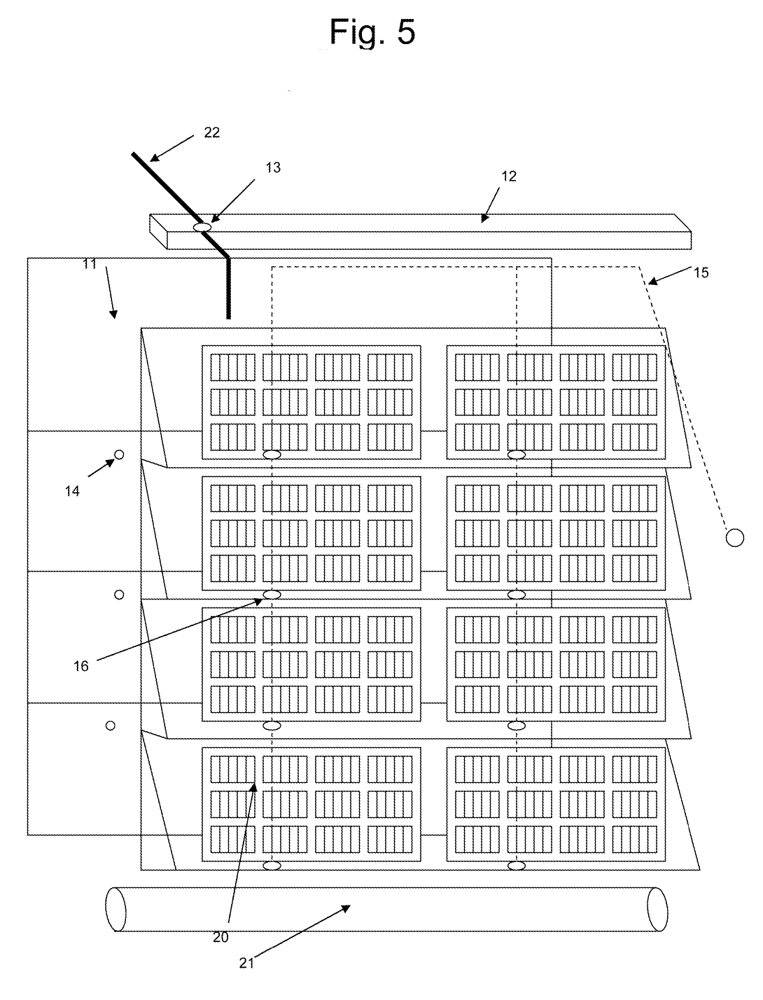

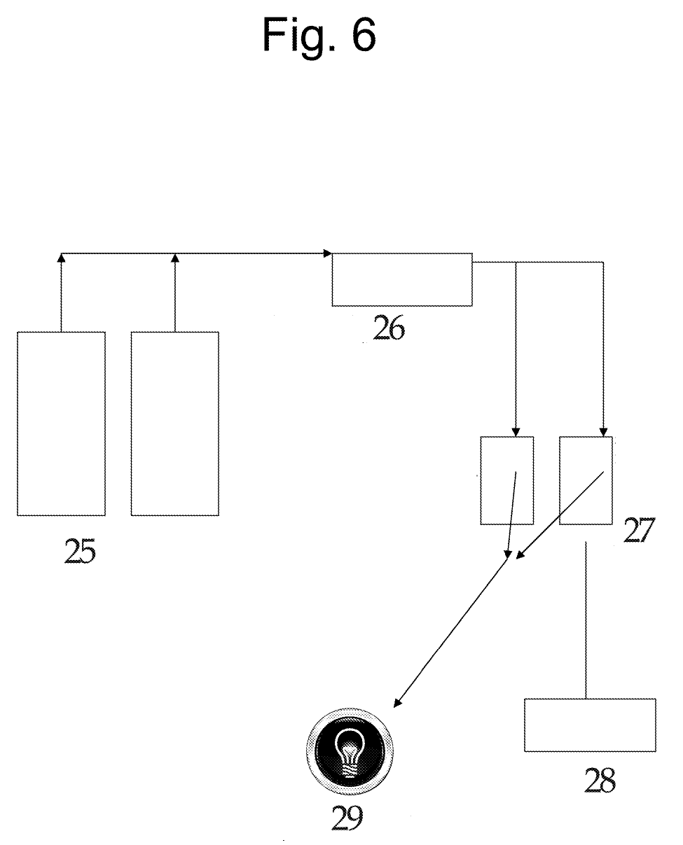

### DETAILED DESCRIPTION OF THE INVENTION

Drawing Summary

Roman Blinds 10 are put together with a Blind Facing Cloth 11 consisting of various fabrics and textures. The Blind Facing Cloth 11 has its upper end fixed to the Top Frame 12. The Top Frame 12 carries the Nylon Cord 15 from the top frame 12 to equal length and distance Horizontal Rods 14 then fit thru each of the Rope Ears 16 connecting stably with the lower end of the blind cloth 11. When pulling or lowering the nylon cord 15 the roman blinds will move respectably.

Flexible Solar Panel 20 is attached to a backing material 21. The backing material is in matching sections to the front of the Roman Blinds, so that when the cord is pulled each section goes up together. The design of the backing material is on a angle to allow for better collection of solar rays. The flexible solar panel 20 collects and transfers it thru a DC Power line 22. •The flexible solar panel's 20 DC Power Cord 22 is run thru the top of the Roman Blind Top Frame 12. The Cloth Backing for the Solar Panels 21 is attached to the Roman Blind Facing Cloth 11. This brings the two main components together to form the invention of Solar Roman Blinds.

Index of Elements

10 Roman Blind

11 Roman Blind Cloth

12 Top Frame

13 Hole for DC Power Line

14 Horizontal Rods

15 Nylon Pull Cord

16 Rope Ears

20 Flexible Solar Panel

21 Backing Material for Flexible Solar Panel

22 DC Power Line

I claim;

1. A solar roman blinds coated with solar energy collecting materials comprised of roman blind cloth (11), top frame (12), DC power source (22), horizontal rods (14), nylon pull cord (15), flexible solar panel (20) and backing material (21).

2. A solar roman blinds of claim 1 wherein the blinds can be raised and lowered.

3. A solar roman blinds of claim 1 wherein exposure to sun generates electrical energy.

4. A solar roman blinds of claim 1 wherein energy is captured while sun rays are blocked for over heating interior spaces.

5. A solar roman blinds of claim 1 wherein energy is produced by sun exposure.

6. A solar roman blinds of claim 1 wherein the blinds can be manufactured from any resin based material.

7. A solar roman blinds of claim 1 wherein the blinds can be manufactured from any metallic based material.

8. A solar roman blinds of claim 1 wherein the solar energy collecting material can be applied as a coating or layer.
